(19) United States
(12) Patent Application Publication
(10) Pub. No.: US 2025/0120116 A1
(43) Pub. Date: Apr. 10, 2025

(54) SEMICONDUCTOR DEVICE INCLUDING VERTICAL GATE-MODULATED CHANNEL REGION

(71) Applicant: Samsung Electronics Co., Ltd., Suwon-si (KR)

(72) Inventors: Suhyun Bang, Suwon-si (KR); Seulji Song, Suwon-si (KR)

(21) Appl. No.: 18/636,661

(22) Filed: Apr. 16, 2024

(30) Foreign Application Priority Data
Oct. 6, 2023 (KR) 10-2023-0145006

(51) Int. Cl. H01L 29/78; H01L 29/08; H01L 29/10; H10B 12/00; H10B 61/00; H10B 63/10

(52) U.S. Cl. CPC H10D 30/63; H10D 62/151; H10D 62/235; H10B 12/482; H10B 61/22; H10B 63/10

(57) ABSTRACT

A vertical semiconductor switching device includes lower and upper conductive patterns, and an active pattern electrically connected between the lower conductive pattern and the upper conductive pattern. The active pattern includes a lower source/drain (S/D) region electrically coupled to the lower conductive pattern, an upper S/D region electrically coupled to the upper conductive pattern, and a channel region having first impurities of a first conductivity type therein, electrically connected to the lower source/drain region and to the upper source/drain region. The channel region includes a lower channel region, an intermediate channel region on the lower channel region, and an upper channel region on the intermediate channel region. A gate electrode is provided on a side surface of the channel region.

### REFERENCE TO PRIORITY APPLICATION

This U.S. non-provisional patent application claims priority under 35 U.S.C. § 119 to Korean Patent Application No. 10-2023-0145006, filed Oct. 26, 2023, the disclosure of which is hereby incorporated herein by reference.

### BACKGROUND

The present disclosure relates to semiconductor devices and, in particular, to semiconductor switching devices (e.g., transistors) having vertical gate-modulated channel regions therein.

As semiconductor devices are scaled down, it becomes increasingly necessary to develop fabrication technologies that are capable of increasing an integration density of semiconductor devices, and improving operation speed and production yield. A semiconductor switching device, such as a vertical channel transistor, has been suggested to improve overall operating characteristics (e.g., integration density, on-state resistance, and current driving capability).

### SUMMARY

An embodiment of the inventive concept provides a semiconductor device having improved electrical characteristics.

According to an embodiment of the inventive concept, a semiconductor device may include a lower conductive pattern on a substrate, an upper conductive pattern on the lower conductive pattern, an active pattern extending between the lower conductive pattern and the upper conductive pattern, and a gate electrode on a side surface of the active pattern. The active pattern may include a lower source/drain region electrically connected to the lower conductive pattern, an upper source/drain region electrically connected to the upper conductive pattern, and a gate-modulated channel region electrically connecting the lower source/drain region to the upper source/drain region and containing a first impurity of a first conductivity type. In some embodiments, the channel region may include a lower channel region, an intermediate channel region, and an upper channel region, which may be sequentially defined in a direction perpendicular to a top surface of the substrate (e.g., for a vertical switching device). A doping concentration of the first impurity in the channel region may decrease in a direction from the lower channel region toward the intermediate channel region and may increase in a direction from the intermediate channel region toward the upper channel region.

According to another embodiment of the inventive concept, a semiconductor device may include a lower conductive pattern on a substrate, an upper conductive pattern on the lower conductive pattern, an active pattern between the lower conductive pattern and the upper conductive pattern, and a gate electrode on a side surface of the active pattern. The active pattern may include a lower source/drain region electrically connected to the lower conductive pattern, an upper source/drain region electrically connected to the upper conductive pattern, and a channel region, which electrically connects the lower source/drain region to the upper source/drain region and contains a first impurity (e.g., dopant) of a first conductivity type. The channel region may include a lower channel region, an intermediate channel region, and an upper channel region, which are sequentially defined in a direction perpendicular to a top surface of the substrate. A doping concentration of the first impurity in the channel region may have a maximum value in the lower channel region or the upper channel region.

According to an embodiment of the inventive concept, a semiconductor device may include a bit line provided on a substrate and extended in a first direction, a data storage pattern on the bit line, an active pattern between the bit line and the data storage pattern, and a gate electrode provided on a side surface of the active pattern and extended in a second direction crossing the first direction. The active pattern may include a lower source/drain region electrically connected to the bit line, an upper source/drain region electrically connected to the data storage pattern, and a channel region that electrically connects the lower source/drain region to the upper source/drain region and contains a first impurity of a first conductivity type. The channel region may include a lower channel region, an intermediate channel region, and an upper channel region, which are sequentially defined in a direction perpendicular to a top surface of the substrate. A doping concentration of the first impurity in the channel region may decrease in a direction from the lower channel region toward the intermediate channel region and may increase in a direction from the intermediate channel region toward the upper channel region.

According to a further embodiment of the inventive concept, a semiconductor switching device is provided, which includes: a substrate having semiconductor source and drain regions of second conductivity type thereon, and a semiconductor channel region of a first conductivity type extending between the source and drain regions. The channel region includes: a source-side channel region that forms a P-N rectifying junction with the source region, a drain-side channel region that forms a P-N rectifying junction with the drain region, and an intermediate channel region extending between the source-side channel region and the drain-side channel region and forming non-rectifying junctions therewith. A gate electrode (e.g., insulated gate electrode) is provided on the channel region. Advantageously, the source-side channel region is more highly doped with first conductivity type impurities relative to the intermediate channel region, and the drain-side channel region is more highly doped with first conductivity type impurities relative to the intermediate channel region. In addition, in some embodiments, the source region includes a relatively more lightly doped source region of second conductivity type in contact with the source-side channel region, and a relatively more highly doped source region of second conductivity type that forms a non-rectifying junction with the relatively more lightly doped source region of second conductivity type. The source, channel and drain regions may also be vertically aligned in a first direction, which is orthogonal to a surface of a substrate, in some embodiments.

### BRIEF DESCRIPTION OF THE DRAWINGS

FIG. 1 is a sectional side view illustrating a vertical channel transistor according to an embodiment of the inventive concept.

FIG. 2 is a graph showing the variation in a doping concentration of the active pattern of FIG. 1 with respect to height.

FIG. 3 is a sectional view illustrating a grain in the active pattern of FIG. 1.

FIG. 4 is a sectional view illustrating a vertical channel transistor according to an embodiment of the inventive concept.

FIG. 5 is a plan layout view illustrating a semiconductor device including a vertical channel transistor, according to an embodiment of the inventive concept.

FIG. 6 is a sectional view taken along a line A-A′ of FIG. 5.

FIGS. 7 to 10 are diagrams illustrating a method of fabricating a semiconductor device including a vertical channel transistor, according to an embodiment of the inventive concept.

### DETAILED DESCRIPTION

Example embodiments of the inventive concepts will now be described more fully with reference to the accompanying drawings, in which example embodiments are shown.

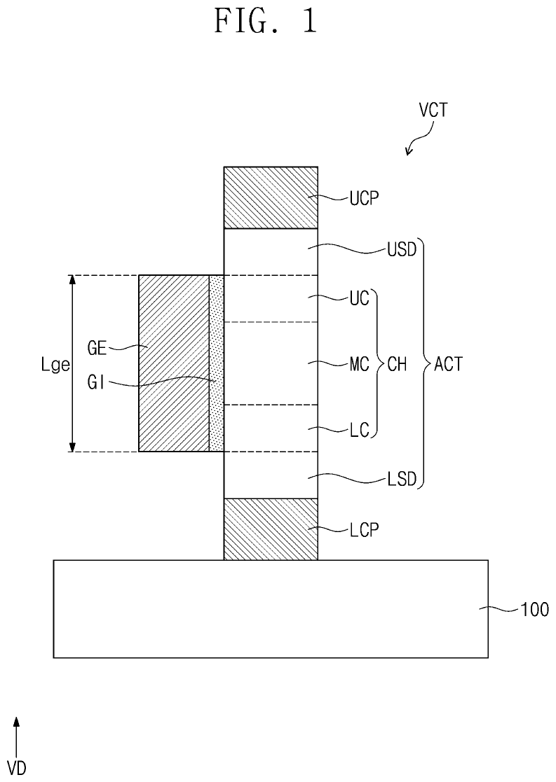

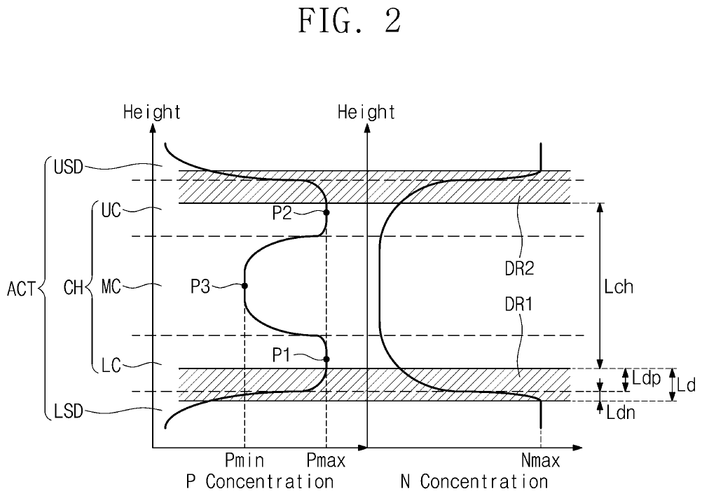

FIG. 1 is a sectional view illustrating a vertical channel transistor according to an embodiment of the inventive concept. FIG. 2 is a graph showing the variation in a doping concentration of the active pattern of FIG. 1 with respect to height. Referring to FIG. 1, a substrate 100 may be provided. The substrate 100 may include at least one of semiconductor materials (e.g., silicon), insulating materials (e.g., silicon oxide), and a semiconductor or conductive layer covered with an insulating layer. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

A vertical channel transistor VCT may be provided on the substrate 100. The vertical channel transistor VCT may include a lower conductive pattern LCP, an upper conductive pattern UCP, an active pattern ACT extending between the lower and upper conductive patterns, and a gate electrode GE and gate insulating pattern GI on a portion of the active pattern ACT, as shown.

The lower conductive pattern LCP may be provided on the substrate 100. The lower conductive pattern LCP may include a conductive material. As an example, the lower conductive pattern LCP may be formed of or include at least one of doped polysilicon, conductive metal nitride materials (e.g., TiN, TaN, WN, NbN, TiAlN, TiSiN, TaSiN, and RuTiN), metallic materials (e.g., Al, Cu, Ti, Ta, Ru, W, Mo, Pt, Ni, and Co), conductive metal oxide materials (e.g., PtO, RuO2, IrO₂, SRO (SrRuO₃), BSRO ((Ba,Sr)RuO₃), CRO (CaRuO₃), and LSCo), conductive two-dimensional materials (e.g., graphene and TMD), or conductive three-dimensional materials (e.g., carbon nanotube). As an example, the lower conductive pattern LCP may be formed of a single material or a composite material including two or more materials.

The upper conductive pattern UCP may be provided on the lower conductive pattern LCP. The upper conductive pattern UCP may be spaced apart from the lower conductive pattern LCP in a vertical direction VD, with the active pattern ACT interposed therebetween. The vertical direction VD may be perpendicular to a top surface of the substrate 100. The upper conductive pattern UCP may or may not be vertically overlapped with the lower conductive pattern LCP.

In an embodiment, the upper conductive pattern UCP may include a conductive material. As an example, the upper conductive pattern UCP may be formed of or include at least one of doped polysilicon, conductive metal nitride materials (e.g., TiN, TaN, WN, NbN, TiAlN, TiSiN, TaSiN, and RuTiN), metallic materials (e.g., Al, Cu, Ti, Ta, Ru, W, Mo, Pt, Ni, and Co), conductive metal oxide materials (e.g., PtO, RuO2, IrO₂, SRO (SrRuO₃), BSRO ((Ba,Sr)RuO₃), CRO (CaRuO₃), and LSCo), conductive two-dimensional materials (e.g., graphene and TMD), or conductive three-dimensional materials (e.g., carbon nanotube). As an example, the upper conductive pattern UCP may be formed of a single material or a composite material including two or more materials.

The active pattern ACT may be provided between the lower and upper conductive patterns LCP and UCP. The active pattern ACT may connect the lower and upper conductive patterns LCP and UCP to each other. In the present specification, the expression “A is connected to B” may be used not only to indicate “A is in direct contact with B” but also to represent the meaning that “A is electrically connected to B through another element even if they are not in direct contact with each other”. The active pattern ACT may be electrically connected to at least one of the lower and upper conductive patterns LCP and UCP through an additional conductive contact (not shown), but the inventive concept is not limited to this example. In an embodiment, the active pattern ACT may be formed of or include at least one of single crystalline doped silicon or poly crystalline doped silicon.

The active pattern ACT may include a lower source/drain region LSD connected to the lower conductive pattern LCP, an upper source/drain region USD connected to the upper conductive pattern UCP, and a channel region CH, which electrically connects the lower and upper source/drain regions LSD and USD to each other. In an embodiment, the lower source/drain region LSD, the channel region CH, and the upper source/drain region USD may be sequentially defined in an upward direction (e.g., as a height in the vertical direction VD increases). The channel region CH may include a lower channel region LC, an intermediate “middle| channel region MC, and an upper channel region UC, which are sequentially provided in an upward direction (e.g., the vertical direction VD).

Each of the channel region CH, the lower source/drain region LSD, and the upper source/drain region USD may contain a first impurity having a first conductivity type (e.g., p-type) and a second impurity having a second conductivity type (e.g., n-type) different from the first conductivity type. In the channel region CH, a concentration of the first impurity may be higher than that of the second impurity. In each of the lower and upper source/drain regions LSD and USD, a concentration of the second impurity may be higher than that of the first impurity. Hereinafter, for convenience of description, the first and second conductivity types will be described to be p-and n-types, respectively, but the inventive concept is not limited to this example.

Referring to FIG. 2, regions of the active pattern ACT may be distinct from each other, based on a height of the doping concentration of the impurity in the active pattern ACT. Here, the x-axis of FIG. 2 may represent a relative value of the doping concentration of the impurity, and the y-axis may represent a relative value of the height of the active pattern ACT. The lower source/drain region LSD, the channel region CH, and the upper source/drain region USD may be defined based on a doping concentration of an n-type impurity. The doping concentration of the n-type impurity may decrease in a direction from the lower source/drain region LSD toward the channel region CH, and the lower source/drain region LSD and the channel region CH may be distinct from each other, based on a height of an inflection point of the doping concentration of the n-type impurity. The doping concentration of the n-type impurity may increase in a direction from the channel region CH toward the upper source/drain region USD, and the channel region CH and the upper source/drain region USD may be distinct from each other, based on a height of an inflection point of the doping concentration of the n-type impurity.

The doping concentration of the n-type impurity may have a maximum value Nmax in the lower source/drain region LSD or the upper source/drain region USD. In an embodiment, the maximum value Nmax of the doping concentration of the n-type impurity may range from 1×10³⁰ cm⁻³ to 5×10²¹ cm⁻³.

The lower channel region LC, the intermediate channel region MC, and the upper channel region UC of the channel region CH may be defined based on a doping concentration of a net p-type impurity. The doping concentration of the p-type impurity may decrease in a direction from the lower channel region LC toward the intermediate channel region MC, and the lower channel region LC and the intermediate channel region MC may be “distinct” from each other, based on a height of an inflection point of the doping concentration of the p-type impurity. The doping concentration of the p-type impurity may increase in a direction from the intermediate channel region MC toward the upper channel region UC, and the intermediate channel region MC and the upper channel region UC may be “distinct” from each other, based on a height of an inflection point of the doping concentration of the p-type impurity.

A maximum value of the doping concentration of the p-type impurity in the lower channel region LC may be P1, and a maximum value of the doping concentration of the p-type impurity in the upper channel region UC may be P2. In an embodiment, in a partially continuous portion of the lower channel region LC, a doping concentration of the p-type impurity may have a substantially uniform value of P1, regardless of a height. As an example, in a partially continuous portion of the upper channel region UC, a doping concentration of the p-type impurity may have a substantially uniform value of P2, regardless of a height. The values P1 and P2 may be equal to or different from each other. In an embodiment, at least one of the values P1 and P2 may be the maximum value Pmax of the doping concentration of the p-type impurity in the channel region CH. The maximum value Pmax may be higher than 9×10¹⁶ cm⁻³ and may be equal to or lower than 2.1×10¹⁸ cm⁻³. If the maximum value Pmax is excessively low, depletion regions DR1 and DR2, which will be described below, may not prevent a punch through phenomenon very effectively. Alternatively, if the maximum value Pmax is excessively high, a leakage current greater than that in the numerical range, may occur.

A minimum value Pmin of the doping concentration of the p-type impurity in the intermediate channel region MC may be P3. In a partially continuous portion of the intermediate channel region MC, a doping concentration of the p-type impurity may have a substantially uniform value of P3, regardless of a height. The minimum value Pmin may range from 9×10¹⁶ cm⁻³ to 2×10¹⁷ cm⁻³. If the minimum value Pmin is excessively low, the on-current characteristics of the semiconductor device may be deteriorated, but if the minimum value Pmin is excessively high, the leakage current may not be effectively suppressed.

The active pattern ACT may include the depletion regions DR1 and DR2. In an embodiment, the depletion regions DR1 and DR2 may include a first depletion region DR1, which is provided to overlap with the lower source/drain region LSD and the channel region CH, and a second depletion region DR2, which is provided to overlap with the upper source/drain region USD and the channel region CH. Lengths Ld of the depletion regions DR1 and DR2 in the vertical direction VD may range from 42 nm to 70 nm. The lengths Ld of the depletion regions DR1 and DR2 may be adjusted depending on the doping concentrations of the lower source/drain region LSD and the lower channel region LC or the doping concentrations of the upper source/drain region USD and the upper channel region UC. Thus, to improve the electrical characteristics of the semiconductor device, the doping concentrations of the channel region CH and the source/drain regions LSD and USD may be adjusted, and the depletion regions DR1 and DR2 may have lengths Ld within the numerical range. When measured in the vertical direction VD, lengths Ldn of the depletion regions DR1 and DR2 in the source/drain regions LSD and USD may be shorter than lengths Ldp of the depletion regions DR1 and DR2 in the channel region CH.

An effective channel length Lch in the channel region CH may be defined as a distance from the first depletion region DR1 to the second depletion region DR2 in the vertical direction VD. The effective channel length Lch may range from 50 nm to 100 nm. If the effective channel length Lch is excessively short, a leakage current property may be deteriorated, due to a punch through phenomenon. If the effective channel length Lch is excessively long, the resistance of the channel region CH may be increased.

According to an embodiment of the inventive concept, the channel region CH may have the first impurity of a high concentration, near the source/drain regions LSD and USD containing the second impurity. Thus, a pair of depletion regions DR1 and DR2 may be locally formed between the channel region CH and the source/drain regions LSD and USD and may be spaced apart from each other. In this case, it may be possible to prevent or suppress a punch through phenomenon, which may occur in the channel region CH when the pair of depletion regions DR1 and DR2 are formed adjacent to each other. As a result, it may be possible to reduce a leakage current, which is caused by the punch through phenomenon, and thereby improve the electrical characteristics of the semiconductor device.

Referring back to FIG. 1, the gate electrode GE may be provided on a side surface of the active pattern ACT. As shown in FIG. 1, the gate electrode GE may be provided on one side surface of the active pattern ACT. As another example, two gate electrodes GE may be respectively provided on opposite side surfaces of the active pattern ACT, unlike the structure illustrated in FIG. 1. In an embodiment, the gate electrode GE may cover a side surface of the channel region CH and may not cover at least a portion or the entirety of a side surface of each of the lower and upper source/drain regions LSD and USD.

The gate electrode GE may include a conductive material. In an embodiment, the gate electrode GE may be formed of or include at least one of doped polysilicon, conductive metal nitride materials (e.g., TiN, TaN, WN, NbN, TiAlN, TiSiN, TaSiN, and RuTiN), metallic materials (e.g., Al, Cu, Ti, Ta, Ru, W, Mo, Pt, Ni, and Co), conductive metal oxide materials (e.g., PtO, RuO2, IrO₂, SRO (SrRuO₃), BSRO ((Ba,Sr)RuO₃), CRO (CaRuO₃), and LSCo), conductive two-dimensional materials (e.g., graphene and TMD), or conductive three-dimensional materials (e.g., carbon nanotube). In an embodiment, the gate electrode GE may be formed of a single material or a composite material including two or more materials.

The gate insulating pattern GI may be interposed between the active pattern ACT and the gate electrode GE. The gate insulating pattern GI may separate the active pattern ACT from the gate electrode GE. Although not illustrated, the gate insulating pattern GI may be further extended in the vertical direction VD or an opposite direction thereof, compared to the gate electrode GE, but the inventive concept is not limited to this example. In an embodiment, the gate insulating pattern GI may be formed of or include at least one of silicon oxide, ferroelectric materials, or high-k dielectric materials. In the present specification, the high-k dielectric material may be defined as a material having a dielectric constant higher than that of silicon oxide. The gate insulating pattern GI may be formed of a single material or a composite material including two or more materials.

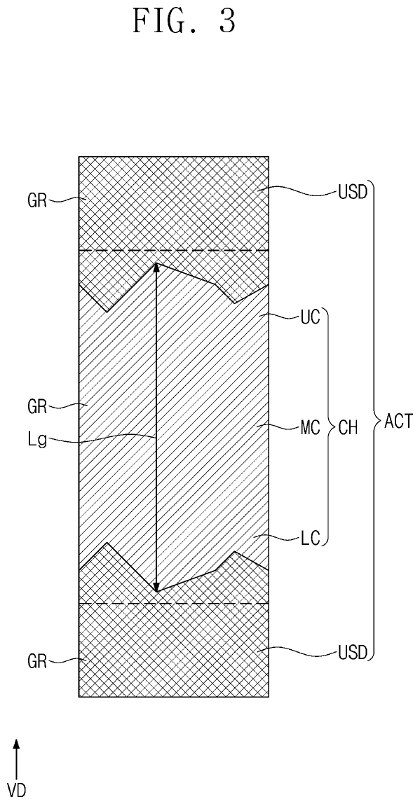

FIG. 3 is a sectional view illustrating a grain in the active pattern of FIG. 1. Referring to FIG. 3, the channel region CH may include a grain GR. The channel region CH may include a single grain GR or a plurality of grains GR. In the case where the number of the grains GR in the channel region CH is reduced, the resistance characteristics of the channel region CH may be improved (i.e., lowered). The grain GR may have a length Lg that is defined in the vertical direction VD. In the case where the channel region CH includes the single grain GR, the length Lg of the grain GR may be defined as the largest length of the single grain GR. In the case where the channel region CH includes a plurality of grains GR, the length Lg of the grain GR may be defined as a length of the longest one of the grains GR in the vertical direction VD. In an embodiment, the length Lg of the grain GR may be larger than the length Lge of the gate electrode GE of FIG. 1 in the vertical direction VD. The length Lg of the grain GR may range from 150 nm to 200 nm. In the case where the length Lg of the grain GR is smaller than 150 nm, the channel region CH may have a short length deteriorating a punch through property. Or the resistance of the channel region CH may be increased, because a plurality of grains GR are provided in the channel region CH having a specific length. In the case where the length Lg of the grain GR is larger than 200 nm, the length of the channel region CH may be increased, and thus, the resistance of the channel region CH may be increased.

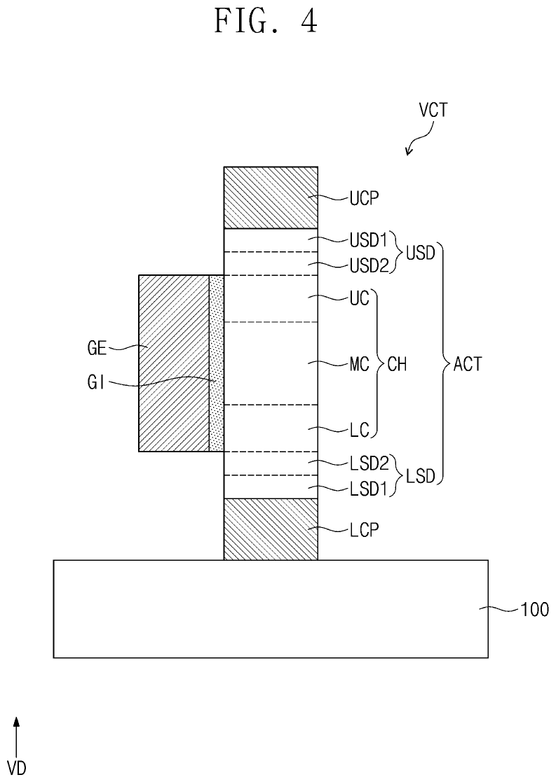

FIG. 4 is a sectional view illustrating a vertical channel transistor according to another embodiment of the inventive concept. Referring to FIG. 4, each of the lower and upper source/drain regions LSD and USD may include a plurality of regions, which are doped with second impurities and have different doping concentrations from each other. In detail, the lower source/drain region LSD may include a first lower source/drain region LSD1 on the substrate 100 and a second lower source/drain region LSD2 extending between the first lower source/drain region LSD1 and the active pattern ACT, as shown. Similarly, the upper source/drain region USD may include a first upper source/drain region USD1 below the upper conductive pattern UCP, and a second upper source/drain region USD2 extending between the first upper source/drain region USD1 and the active pattern ACT, as shown.

The doping concentration of the second impurity may be higher in the first lower source/drain region LSD1 than in the second lower source/drain region LSD2, and a doping concentration of the first upper source/drain region USD1 may be higher than that of the second upper source/drain region USD2. That is, the second lower and upper source/drain regions LSD2 and USD2 may be relatively lightly doped drain (LDD) regions, and in this case, a leakage current in the vertical channel transistor VCT may be reduced.

In each of the first lower source/drain region LSD1 and the first upper source/drain region USD1, a maximum value of the doping concentration of the second impurity may range from 1×10²⁰ cm⁻³ to 5×10²¹ cm⁻³. In each of the second lower and upper source/drain regions LSD2 and USD2, the doping concentration of the second impurity may decrease, for example, in a stepwise manner, as a distance to the channel region CH decreases. Here, in a partially continuous portion of each of the second lower and upper source/drain regions LSD2 and USD2, a doping concentration of the second impurity may be substantially uniform, and the uniform value may range from 5×10¹⁸ cm⁻³ to 1×10²⁰ cm⁻³, regardless of a height.

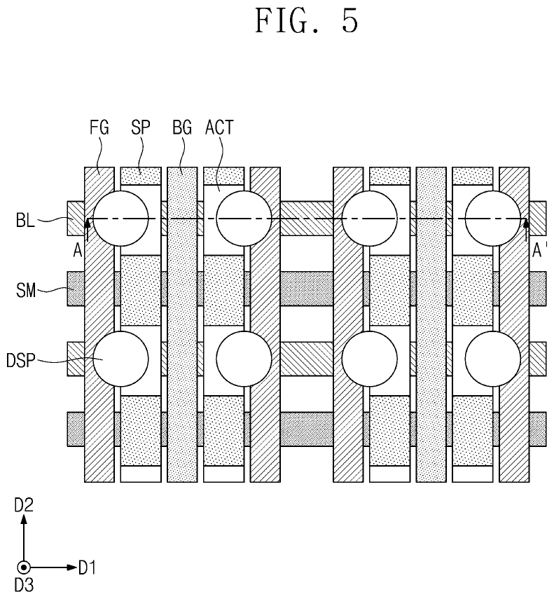

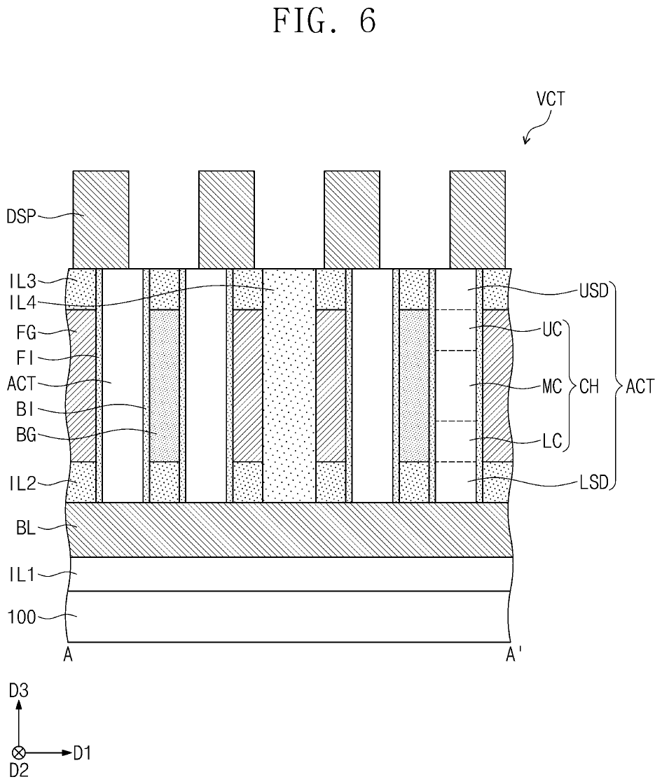

FIG. 5 is a plan view illustrating a semiconductor device including a vertical channel transistor, according to an embodiment of the inventive concept. FIG. 6 is a sectional view taken along a line A-A′ of FIG. 5. Hereinafter, the semiconductor device including the vertical channel transistor will be exemplarily described in more detail with reference to FIGS. 5 and 6. For concise description, a previously described element may be identified by the same reference number without repeating an overlapping description thereof.

Referring to FIGS. 5 and 6, the substrate 100 and the vertical channel transistor VCT thereon may be provided. The substrate 100 and the vertical channel transistor VCT may correspond to the substrate 100 and the vertical channel transistor VCT of FIG. 1. The vertical channel transistor VCT may include a bit line BL, a data storage pattern DSP, an active pattern ACT, gate electrodes FG and BG, and a gate insulating pattern GI. The bit line BL, the data storage pattern DSP, the active pattern ACT, the gate electrodes FG and BG, and the gate insulating pattern GI may correspond to the lower conductive pattern LCP, the upper conductive pattern UCP, the active pattern ACT, the gate electrode GE, and the gate insulating pattern GI of FIG. 1, respectively, and may have similar features to the corresponding elements.

The vertical channel transistor VCT may further include first to fourth insulating layers IL1, IL2, IL3, and IL4, a shielding structure SM, and separation patterns SP. Each of the first to fourth insulating layers IL1, IL2, IL3, and IL4 may be formed of or include at least one of silicon oxide, silicon nitride, silicon oxynitride, silicon carbon nitride, tetraethyl orthosilicate (TEOS), and low-k dielectric materials. In the present specification, the low-k dielectric material may be defined as a material having a dielectric constant lower than silicon oxide. Each of the first to fourth insulating layers IL1, IL2, IL3, and IL4 may be formed of a single material or a composite material of two or more materials.

The first insulating layer IL1 may be provided on the substrate 100. The bit line BL and the shielding structure SM may cross the first insulating layer IL1 in a first direction D1 that is parallel to the top surface of the substrate 100. The first insulating layer IL1 may enclose side and bottom surfaces of the bit line BL but may not enclose a top surface of the bit line BL.

The shielding structure SM may be provided between bit lines BL, which are adjacent to each other in a second direction D2. The second direction D2 may be parallel to the top surface of the substrate 100 and may not be parallel to the first direction D1. Although not shown, the shielding structure SM may include a plurality of extended portions, which are interposed between adjacent ones of the bit lines BL, and an extended portion, which is placed below the adjacent ones of the bit lines BL to connect the extended portions to each other. The shielding structure SM may include a conductive material. The shielding structure SM may suppress an interference phenomenon between the bit lines BL.

The active pattern ACT may be provided on the bit line BL. When viewed in a plan view, a plurality of active patterns ACT may be disposed to be spaced apart from each other in the first and second directions D1 and D2. Each of the active patterns ACT may be extended in a third direction D3 that is perpendicular to the top surface of the substrate 100. The third direction D3 may correspond to the vertical direction VD of FIG. 1. Each of the active patterns ACT may include the lower source/drain region LSD, the upper source/drain region USD, and the channel region CH connecting them to each other. The channel region CH may include the lower channel region LC, the intermediate channel region MC, and the upper channel region UC.

The separation patterns SP may be provided to separate the active patterns ACT from each other and to electrically disconnect the active patterns ACT from each other. The separation patterns SP may include an insulating material.

The gate electrodes FG and BG may be provided on the side surface of the active pattern ACT. The gate electrodes FG and BG may include a front-gate electrode FG and a back-gate electrode BG, which are respectively provided on opposite side surfaces of the active pattern ACT. The front-gate electrode FG may be extended along side surfaces of the active patterns ACT, which are arranged to form a single column in the second direction D2. The back-gate electrode BG may be extended along opposite side surfaces of the column of the active patterns ACT or in the second direction D2. In an embodiment, a pair of the active patterns ACT, which are adjacent to each other in the first direction D1, may share one of the back-gate electrodes BG, and the back-gate electrode BG may be interposed between the pair of active patterns ACT. A pair of front-gate electrodes FG may be provided on the pair of active patterns ACT, respectively.

The gate insulating pattern GI may be interposed between the gate electrodes FG and BG and the active pattern ACT. As an example, the gate insulating pattern GI may be interposed between the front-gate electrode FG and the active pattern ACT and between the back-gate electrode BG and the active pattern ACT.

The second insulating layer IL2 may be provided below the gate electrodes FG and BG. The second insulating layer IL2 may be interposed between the gate electrodes FG and BG and the bit line BL. The third insulating layer IL3 may be provided on the gate electrodes FG and BG. The third insulating layer IL3 may cover top surfaces of the gate electrodes FG and BG. The fourth insulating layer IL4 may be interposed between the front-gate electrodes FG, which are adjacent to each other in the first direction D1. In an embodiment, the active patterns ACT may be provided on side surfaces of the adjacent ones of the front-gate electrodes FG, respectively, and the fourth insulating layer IL4 may be interposed between opposite side surfaces of the adjacent ones of the front-gate electrodes FG.

The data storage pattern DSP may be provided on the active pattern ACT. In an embodiment, a plurality of data storage patterns DSP may be connected to the active patterns ACT, respectively. In an embodiment, the data storage pattern DSP may be offset from a corresponding one of the active patterns ACT in a horizontal direction (e.g., the first direction D1), but the inventive concept is not limited to this example. A conductive contact (not shown) may electrically connect the data storage pattern DSP to the active pattern ACT (e.g., the upper source/drain region USD), and the data storage pattern DSP and the active pattern ACT may be spaced apart from each other in the third direction D3, although not illustrated.

In an embodiment, the data storage pattern DSP may be a capacitor including a bottom electrode, a top electrode, and a dielectric layer therebetween. The dielectric layer may be formed of or include at least one of paraelectric materials, ferroelectric materials, and anti-ferroelectric materials. Here, the semiconductor device may be a volatile memory device and a nonvolatile memory device, depending on the material of the dielectric layer and the combination thereof. As another example, the data storage pattern DSP may include a magnetic tunnel junction pattern. As other example, the data storage pattern DSP may include a phase change material or a variable resistance material. However, the inventive concept is not limited to these examples, and the data storage pattern DSP may include various structures and/or materials which can be used to store data.

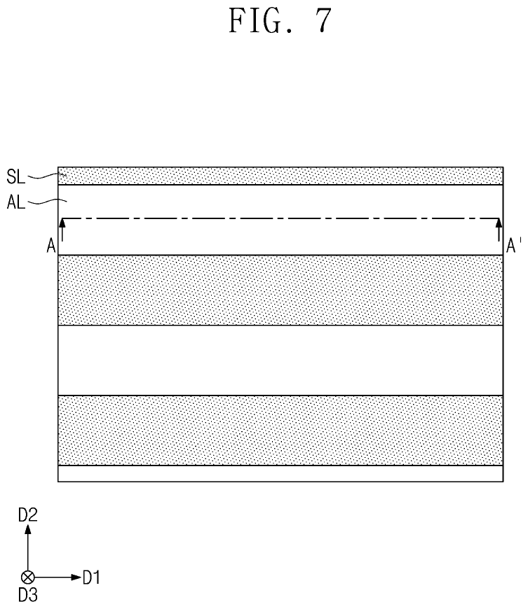

FIGS. 7 to 10 are diagrams illustrating a method of fabricating a semiconductor device including a vertical channel transistor, according to an embodiment of the inventive concept. For concise description, a previously described element may be identified by the same reference number without repeating an overlapping description thereof. According to some embodiments, the structure of FIGS. 7 to 10 may be flipped in a specific step of the fabrication process. For example, the structure of FIGS. 7 to 10 may be a flipped structure of the final structure of the semiconductor device of FIGS. 5 and 6.

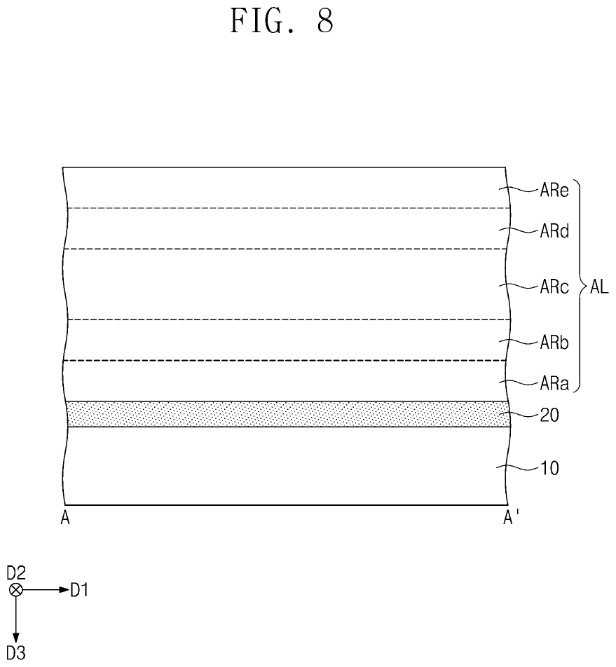

Referring to FIGS. 7 and 8, a base substrate 10 may be provided, and an insulating substrate 20 may be formed on the base substrate 10. The insulating substrate 20 may be formed to cover a top surface of the base substrate 10. The base substrate 10 may be formed of or include a semiconductor material (e.g., silicon), and the insulating substrate 20 may be formed of or include an insulating material (e.g., silicon oxide).

An active layer (not shown) may be formed on the insulating substrate 20. As an example, the active layer may be formed to cover a top surface of the insulating substrate 20. The active layer may be formed of or include at least one of single-crystalline silicon and polysilicon.

An active line AL may be formed by etching the active layer. For example, the active layer may be etched to form a plurality of active lines AL which are separated from each other. The active lines AL may be extended in the first direction D1 and may be spaced apart from each other in the second direction D2. Separation lines SL may be formed in regions, in which the active layer is etched. The separation lines SL may separate the active lines AL from each other in the second direction D2.

The active line AL may include a first region ARa, a second region ARb, a third region ARc, a fourth region ARd, and a fifth region ARe, which are sequentially provided in an upward direction. The first to fifth regions ARa, ARb, ARc, ARd, and ARe may sequentially correspond to the upper source/drain region USD, the upper channel region UC, the intermediate channel region MC, the lower channel region LC, and the lower source/drain region LSD of FIG. 1, and in this case, the doping concentration of the impurity may be similar to that shown in FIG. 2. The first to fifth regions ARa, ARb, ARc, ARd, and ARe may be formed through various methods. In an embodiment, the first to fifth regions ARa, ARb, ARc, ARd, and ARe may be formed by controlling a process condition in an ion implantation process, which is performed as a part of the formation of the active layer or the active line AL. In another embodiment, the first to fifth regions ARa, ARb, ARc, ARd, and ARe may be formed by controlling the concentration of the impurity from region to region, during the formation of the active layer.

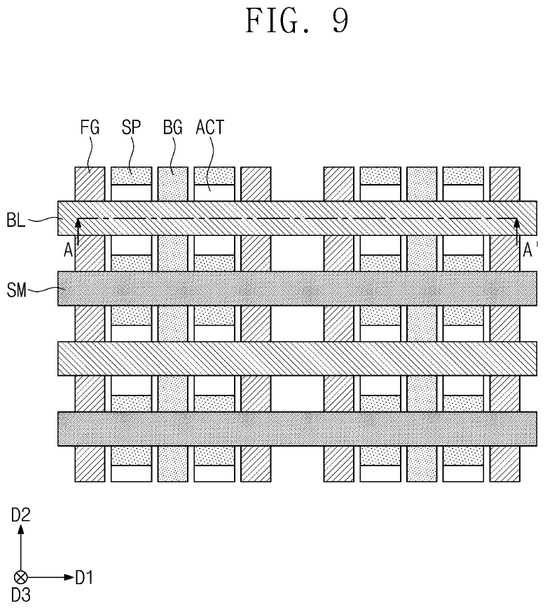

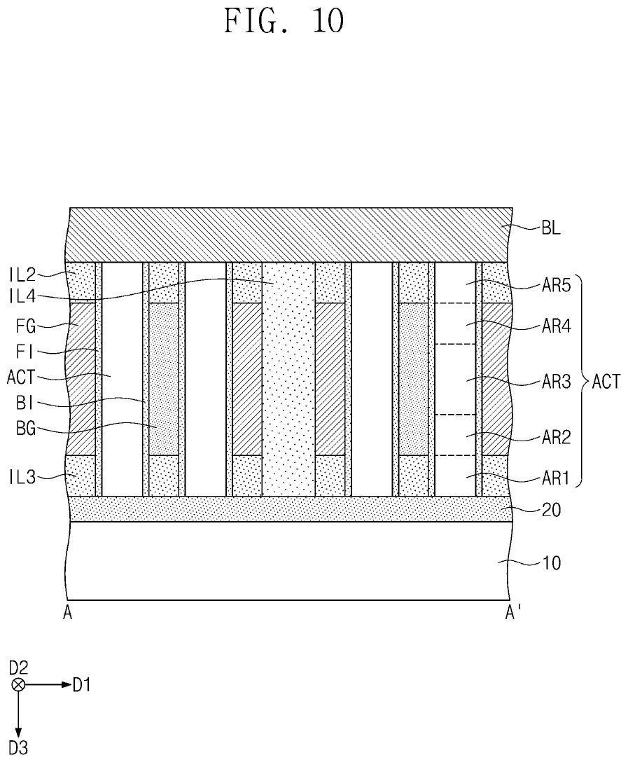

Referring to FIGS. 9 and 10, the active and separation patterns ACT and SP may be formed from the active line AL and the separation line SL, respectively. The formation of the active and separation patterns ACT and SP may include etching the active line AL and the separation line SL. In an embodiment, one active line AL may be etched to form a plurality of active patterns ACT, which are arranged in the first direction D1 to form a single row and are spaced apart from each other. In an embodiment, one separation line SL may be etched to form a plurality of separation patterns SP, which are arranged in the first direction D1 to form a single row and are spaced apart from each other. After the separation process, the first to fifth regions ARa, ARb, ARc, ARd, and ARe of the active line AL may be defined as first to fifth regions AR1, AR2, AR3, AR4, and AR5 of the active pattern ACT, respectively.

The gate electrodes FG and BG may be formed on the side surface of the active pattern ACT. The formation of the gate electrodes FG and BG may include forming the front-gate electrode FG and the back-gate electrode BG at the same time. In an embodiment, the formation of the gate electrodes FG and BG may include forming the front-gate electrode FG and the back-gate electrode BG through different processes from each other. In an embodiment, the back-gate electrode BG may be formed, and then, the front-gate electrode FG may be formed through an additional process.

The second to fourth insulating layers IL2, IL3, and IL4 may be formed, before and after the formation of the gate electrodes FG and BG. The second to fourth insulating layers IL2, IL3, and IL4 may be formed at various times, depending on the formation order of the front-and back-gate electrodes FG and BG. Although not illustrated, the third insulating layer IL3 may be formed after a bonding process to be described below, but the inventive concept is not limited to this example.

Thereafter, the bit line BL may be formed on the active pattern ACT, and the shielding structure SM may be formed on the separation pattern SP. The formation of the bit line BL and the shielding structure SM may include sequentially forming the bit line BL and the shielding structure SM.

Referring back to FIGS. 5 and 6, the first insulating layer IL1 may be formed on the bit line BL, and the substrate 100 may be formed on the first insulating layer IL1. The formation of the substrate 100 may include bonding the substrate 100 to the first insulating layer IL1. Thereafter, the afore-described structure may be flipped. As a result of the flip process, the substrate 100 may be placed at a lower level, and the base substrate 10 and the insulating substrate 20 may be placed at an upper level. The first to fifth regions AR1, AR2, AR3, AR4, and AR5 of FIG. 10 may be defined as the upper source/drain region USD, the upper channel region UC, the intermediate channel region MC, the lower channel region LC, and the lower source/drain region LSD, respectively.

The base substrate 10 and the insulating substrate 20 may be removed. The data storage pattern DSP may be formed on the active pattern ACT. Although not shown, a conductive contact may be formed to connect the data storage pattern DSP to the active pattern ACT.

According to an embodiment of the inventive concept, a pair of depletion regions may be locally formed between a channel region and a pair of source/drain regions. In this case, it may be possible to prevent or suppress a punch through phenomenon, which may occur in the channel region when the pair of depletion regions are formed adjacent to each other. As a result, it may be possible to reduce a leakage current, which is caused by the punch through phenomenon, and thereby improve the electrical characteristics of the semiconductor device.

While example embodiments of the inventive concept have been particularly shown and described, it will be understood by one of ordinary skill in the art that variations in form and detail may be made therein without departing from the spirit and scope of the attached claims.

1. A semiconductor device, comprising:
a lower conductive pattern on a substrate;
an upper conductive pattern;
an active pattern electrically connected between the lower conductive pattern and the upper conductive pattern, said active pattern comprising:
a lower source/drain region electrically coupled to the lower conductive pattern;
an upper source/drain region electrically coupled to the upper conductive pattern; and
a channel region having first impurities of a first conductivity type therein, electrically connected to the lower source/drain region and to the upper source/drain region, said channel region including: a lower channel region, an intermediate channel region on the lower channel region, and an upper channel region on the intermediate channel region, and having a first impurity doping concentration therein that decreases in a direction from the lower channel region toward the intermediate channel region and increases in a direction from the intermediate channel region toward the upper channel region; and
a gate electrode on a side surface of the channel region.

2. The semiconductor device of claim 1, wherein an effective channel length in the channel region ranges from 50 nm to 100 nm in a vertical direction, which extends from the lower source/drain region to the upper source/drain region.

3. The semiconductor device of claim 1, wherein a maximum of the first impurity doping concentration in the channel region is located in at least one of the lower channel region and the upper channel region.

4. The semiconductor device of claim 3, wherein the maximum of the first impurity doping concentration in the channel region is in a range from 9×10¹⁶ cm⁻³ to 2.1×10¹⁸ cm⁻³.

5. The semiconductor device of claim 1, wherein the first conductivity type impurity is a p-type impurity.

6. The semiconductor device of claim 1, wherein the channel region is configured as a single or multiple grain region; and wherein a length of at least one grain in the channel region, as measured in a vertical direction, which extends from the lower source/drain region to the upper source/drain region, is greater than a length of the gate electrode in the vertical direction.

7. The semiconductor device of claim 1, wherein the channel region is configured as a single or multiple grain region; and wherein a length of at least one grain in the channel region, as measured in a vertical direction, which extends from the lower source/drain region to the upper source/drain region, is in a range from 150 nm to 200 nm.

8. The semiconductor device of claim 1, wherein a minimum of the first impurity doping concentration in the intermediate channel region ranges from 9×10¹⁶ cm⁻³ to 2×10¹⁷ cm⁻³.

9. The semiconductor device of claim 1,
wherein each of the lower source/drain region and the upper source/drain region includes second impurities of a second conductivity type therein, which is different from the first conductivity type;
wherein the lower source/drain region includes a first lower source/drain region on the substrate and a second lower source/drain region extending between the first lower source/drain region and the active pattern;
wherein the upper source/drain region includes a first upper source/drain region below the upper conductive pattern and a second upper source/drain region extending between the first upper source/drain region and the active pattern;
wherein the first and second lower source/drain regions have different concentrations of the second impurity therein; and
wherein the first and second upper source/drain regions have different concentrations of the second impurity therein.

10. The semiconductor device of claim 9, wherein the doping concentration of the second impurity is higher in the first lower source/drain region than in the second lower source/drain region and is higher in the first upper source/drain region than in the second upper source/drain region.

11. The semiconductor device of claim 1, wherein a depletion region that overlaps the upper source/drain region and the channel region has a built-in width in a range from 42 nm to 70 nm, as measured in a vertical direction, which extends from the lower source/drain region to the upper source/drain region.

12. The semiconductor device of claim 11, wherein a width of the depletion region in the upper source/drain region is less than a width of the depletion region in the channel region, as measured in the vertical direction.

13. A semiconductor device, comprising:
a lower conductive pattern on a substrate;
an upper conductive pattern on the lower conductive pattern;
an active pattern extending between the lower conductive pattern and the upper conductive pattern, said active pattern comprising:
a lower source/drain region electrically connected to the lower conductive pattern;
an upper source/drain region electrically connected to the upper conductive pattern; and
a channel region electrically coupling the lower source/drain region to the upper source/drain region and containing a first impurity of a first conductivity type therein, said channel region including a lower channel region, an intermediate channel region, and an upper channel region, which are sequentially defined in a direction perpendicular to a top surface of the substrate, and having a first impurity doping concentration therein that is at a maximum in at least one of the lower channel region or the upper channel region relative to the intermediate channel region; and
a gate electrode on a side surface of the channel region.

14. The semiconductor device of claim 13, wherein the maximum value of the doping concentration of the first impurity in the channel region ranges from 9×10¹⁶ cm⁻³ to 2.1×10¹⁸ cm⁻³.

15. The semiconductor device of claim 13, wherein the channel region comprises a single grain or a plurality of grains; and wherein a length of the single grain in a vertical direction extending between the lower and upper conductive patterns, or a length of at least one of the plurality of grains in the vertical direction ranges from 150 nm to 200 nm.

16. The semiconductor device of claim 13, further comprising a depletion region, which is defined to overlap with the lower source/drain region and the channel region; and wherein a length of the depletion region in the vertical direction ranges from 42 nm to 70 nm.

17. The semiconductor device of claim 16, wherein a length of the depletion region in the lower source/drain region is shorter than a length of the depletion region in the channel region.

18. A semiconductor device, comprising:
a bit line provided on a substrate and extended in a first direction;
a data storage pattern on the bit line;
an active pattern between the bit line and the data storage pattern; and
a gate electrode provided on a side surface of the active pattern and extended in a second direction crossing the first direction;
wherein the active pattern comprises a lower source/drain region connected to the bit line, an upper source/drain region connected to the data storage pattern, and a channel region connecting the lower source/drain region to the upper source/drain region and containing a first impurity of a first conductivity type;
wherein the channel region comprises a lower channel region, an intermediate channel region, and an upper channel region, which are sequentially defined in a direction perpendicular to a top surface of the substrate; and
wherein a doping concentration of the first impurity in the channel region decreases in a direction from the lower channel region toward the intermediate channel region and increases in a direction from the intermediate channel region toward the upper channel region.

19. The semiconductor device of claim 18, wherein the data storage pattern includes a bottom electrode, a top electrode, and a dielectric layer therebetween; and wherein the dielectric layer includes at least one of paraelectric, ferroelectric, and anti-ferroelectric materials.

20. The semiconductor device of claim 18, wherein the data storage pattern and the active pattern are electrically connected to each other through a conductive contact extending therebetween.

21.-23. (canceled)
